(19) United States
(12) Patent Application Publication
(10) Pub. No.: US 2025/0338627 A1
(43) Pub. Date: Oct. 30, 2025

(54) OSCILLATOR CIRCUIT, LAYOUT, AND METHOD

(71) Applicants: TAIWAN SEMICONDUCTOR MANUFACTURING COMPANY, LTD., Hsinchu (TW); TSMC NANJING COMPANY, LIMITED, Nanjing (CN)

(72) Inventors: Yi Yun HUANG, Hsinchu (TW); Po-Yu CHEN, Hsinchu (TW); Feng LIN, Hsinchu (TW); Zhang-Ying YAN, Hsinchu (TW); XingYu LIU, Hsinchu (TW); Pingyu LI, Hsinchu (TW); Yun Hao LIU, Hsinchu (TW); SiLiang XIE, Hsinchu (TW); Qingchao MENG, Hsinchu (TW)

(21) Appl. No.: 18/748,954

(22) Filed: Jun. 20, 2024

(30) Foreign Application Priority Data
Apr. 30, 2024 (CN) 202410546608.8

(51) Int. Cl. H01L 27/02; H01L 27/092; H03B 5/04

(52) U.S. Cl. CPC H10D 89/10; H03B 5/04; H10D 84/856

(57) ABSTRACT

An integrated circuit (IC) includes a voltage source configured to generate a first voltage having a temperature-dependent voltage level, and a voltage-controlled oscillator (VCO) including a feedback path and a first VCO cell configured to receive the first voltage. The first VCO cell includes a series of stages, a first stage of the series of stages is configured to output a first signal internal to the first VCO cell based on the voltage level of the first voltage and an oscillation signal propagated on the feedback path, and a last stage of the series of stages is configured to output a second signal external to the first VCO cell based on the first signal and the voltage level of the first voltage.

### PRIORITY

This application claims priority to Chinese Application No. 202410546608.8, filed Apr. 30, 2024, which is incorporated herein by reference in its entirety.

### BACKGROUND

The ongoing trend in miniaturizing integrated circuits (ICs) has resulted in progressively smaller devices which consume less power, yet provide more functionality at higher speeds than earlier technologies. To monitor power consumption, ICs sometimes include circuits with properties that vary along with power-related heat generation. Such circuits can include voltage-controlled oscillators (VCOs) in which temperature-dependent voltages are used to control oscillation frequencies. The resultant frequencies serve as temperature sensors that can used to obtain temperature variation maps capable of providing feedback on IC design and manufacturing efforts, or as signoff tools for products built using a variety of manufacturing processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of an IC, in accordance with some embodiments.

FIGS. 2A-2C are plan views of IC layouts and corresponding multistage voltage-controlled oscillator (VCO) cells, in accordance with some embodiments.

FIGS. 3A-3E are plan views of IC layouts and corresponding VCO circuits, in accordance with some embodiments.

FIG. 4 is a schematic diagram of a voltage source, in accordance with some embodiments.

FIG. 5 is a schematic diagram of a VCO stage, in accordance with some embodiments.

FIG. 6 is a schematic diagram of a multistage VCO cell, in accordance with some embodiments.

FIG. 7 is a schematic diagram of a multistage VCO cell, in accordance with some embodiments.

FIG. 8 is a schematic diagram of a multibit VCO cell, in accordance with some embodiments.

FIG. 9 is a schematic diagram of an IC, in accordance with some embodiments.

FIG. 10 is a flowchart of a method of operating an IC, in accordance with some embodiments.

FIG. 11 is a flowchart of a method of manufacturing an IC, in accordance with some embodiments.

FIG. 12 is a flowchart of a method of generating an IC layout diagram, in accordance with some embodiments.

FIG. 13 is a block diagram of an IC layout diagram generation system, in accordance with some embodiments.

FIG. 14 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, steps, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, an oscillator integrated circuit (IC), layout and method include a temperature-dependent voltage source and a voltage-controlled oscillator (VCO) including one or more multistage VCO cells and a feedback path. Each multistage VCO cell receives the temperature-dependent voltage whereby the VCO outputs a signal having a frequency indicative of the temperature of the voltage source. Compared to approaches that are not based on multistage VCO cells, the IC is capable of outputting the signal using less area while maintaining thermal linear sensitivity.

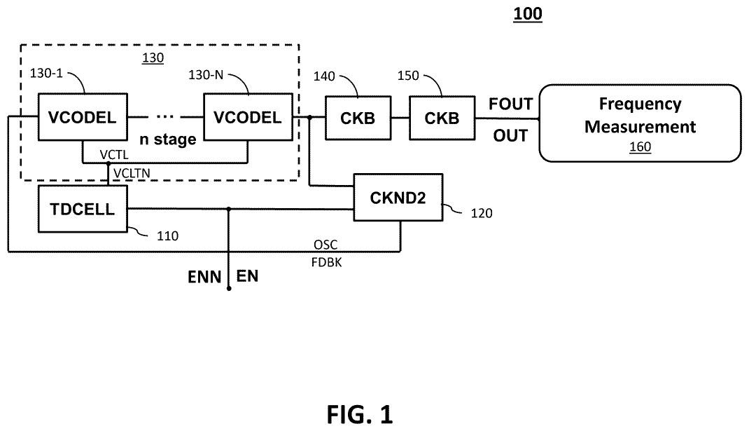

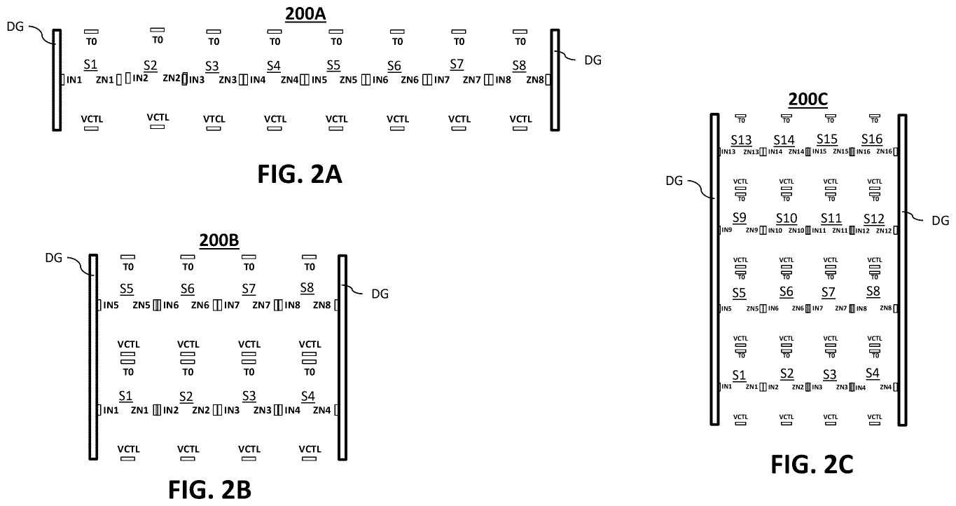

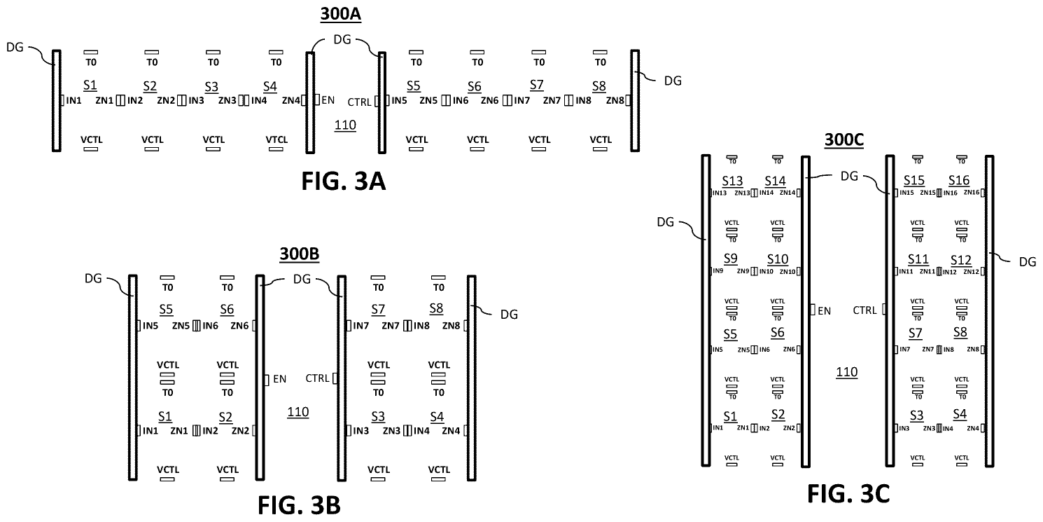

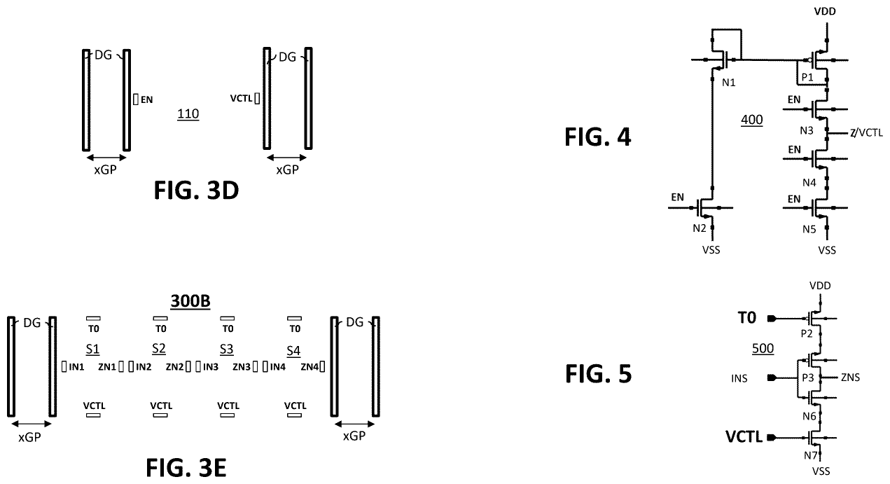

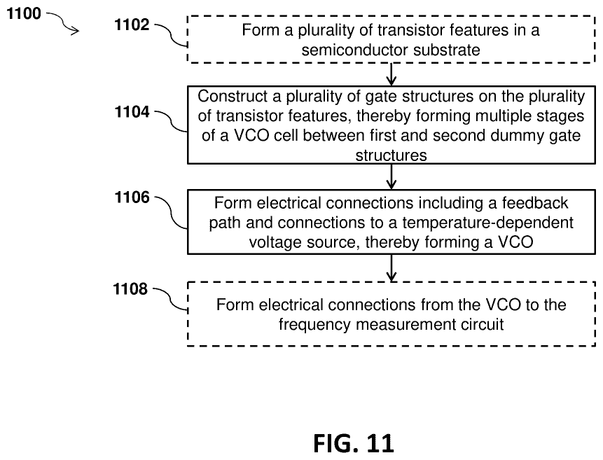

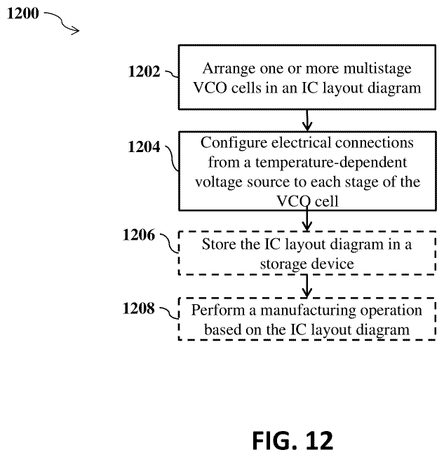

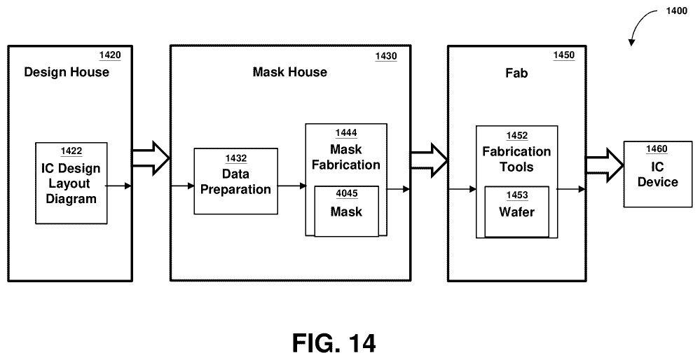

As discussed below, FIG. 1 is a schematic diagram of an oscillator IC including a VCO, FIGS. 2A-3E depict plan views of IC layout diagrams and corresponding VCO circuits, and FIGS. 4-8 are schematic diagrams of VCO circuits, in some embodiments. Each of FIGS. 2A-3E is a circuit/layout diagram in which the reference designators represent both IC features and the IC layout features used to at least partially define the corresponding IC features in a manufacturing process, e.g., a method 1100 discussed below with respect to FIG. 11 and/or an IC manufacturing flow associated with an IC manufacturing system 1400 discussed below with respect to FIG. 14. In some embodiments, one or more of FIGS. 2A-3E is some or all of an IC layout diagram generated by executing some or all of the operations of a method 1200 discussed below with respect to FIG. 12. Accordingly, each of FIGS. 2A-3E represents a plan view of both an IC layout diagram and a corresponding IC device.

Each of the figures herein, e.g., FIGS. 2A-3E, is simplified for the purpose of illustration. The figures are views of IC structures and devices with various features included and excluded to facilitate the discussion below. In various embodiments, an IC structure, device and/or layout diagram includes one or more features corresponding to power distribution structures, metal interconnects, contacts, vias, gate structures, source/drain (S/D) structures, or other transistor elements, isolation structures, or the like, in addition to the features depicted in FIGS. 2A-3E.

The positioning and relative sizes of the various features depicted in FIGS. 2A-3E are non-limiting examples provided for the purpose of illustration. In various embodiments, the IC layouts/circuits depicted in FIGS. 2A-3E include features otherwise positioned and/or sized within the corresponding IC layouts/circuits.

FIG. 1 is a schematic diagram of an IC 100, in accordance with some embodiments. In some embodiments, IC 100 is referred to as oscillator circuit 100, temperature sensor 100, thermal ring 100, or VCO circuit 100.

IC 100 includes a voltage source 110, a switching circuit 120, VCO cells 130-1-130-N (collectively VCO cells 130), buffers 140 and 150, and a frequency measurement circuit 160. In some embodiments, as depicted in FIG. 1, voltage source 110 is referred to as TDCELL 110, switching circuit 120 is referred to as CKND2 120, VCO cells 130-1-130-N are referred to as VCODEL 130-1-130-N, and/or buffers 140 and 150 are referred to as CKB 140 and 150.

Each of voltage source 110 and switching circuit 120 is configured to receive an enable signal EN on a signal node ENN from an external circuit (not shown), e.g., a control circuit. A feedback path FDBK is configured to propagate an oscillation signal OSC from an output terminal (not labeled) of VCO cell 130-N to an input terminal (not labeled) of VCO cell 130-1, and includes switching circuit 120 in the embodiment depicted in FIG. 1. In some embodiments, IC 100 and feedback path FDBK do not include switching circuit 120 and feedback path FDBK is configured to directly couple the output terminal of VCO cell 130-N to the input terminal of VCO cell 130-1.

In the embodiment depicted in FIG. 1, buffers 140 and 150 are coupled in series between the output terminal of VCO cell 130-N and frequency measurement circuit 160 and are thereby configured to output a signal FOUT to frequency measurement circuit 160 on an output node OUT. In some embodiments, IC 100 does not include buffers 140 and 150, and feedback path FDBK is directly coupled to output node OUT and thereby configured to output oscillation signal OSC as signal FOUT on output node OUT. In some embodiments, IC 100 does not include one of buffers 140 or 150 or includes one or more buffers (not shown) in addition to buffers 140 and 150 and is thereby configured to output signal FOUT on output node OUT.

In some embodiments, VCO cells 130 and feedback path FDBK, including switching circuit 120 if present, and buffers 140 and 150, if present, are referred to as a VCO configured to output signal FOUT responsive to a voltage VCTL received on voltage node VCTLN.

Voltage source 110, also referred to as temperature-dependent (TD) voltage source 110 in some embodiments, is an electronic circuit configured to output voltage VCTL on voltage node VCTLN having either a predefined voltage level or a temperature-dependent voltage level responsive to enable signal EN.

Enable signal EN is configured to have a first logic level, e.g., a high logic level, configured to cause voltage source 110 to output voltage VCTL having the temperature-dependent voltage level, and a second logic level, e.g., a low logic level, configured to cause voltage source 110 to output voltage VCTL having the predetermined voltage level being one of the first or second logic levels, e.g., the low logic level.

In some embodiments, the low logic level is a voltage level within a predetermined range of a reference voltage of IC 100, e.g., reference voltage VSS discussed below, and the high logic level is a voltage level within a predetermined range of a power supply voltage of IC 100, e.g., power supply voltage VDD discussed below.

In some embodiments, voltage source 110 is configured to output voltage VCTL having the temperature-dependent voltage level configured to increase as a function of increasing temperature. In some embodiments, voltage source 110 is configured to output voltage VCTL having the temperature-dependent voltage level configured to decrease as a function of increasing temperature.

In some embodiments, voltage source 110 includes voltage source 400 discussed below with respect to FIG. 4.

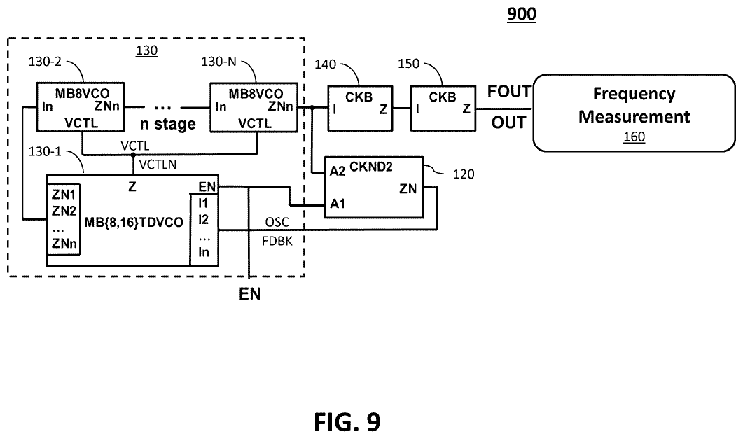

In some embodiments, IC 100 does not include voltage source 110, and instead one or more of VCO cells 130, e.g., VCO cell 130-1 of IC 900 discussed below with respect to FIG. 9, includes a voltage source component configured to output voltage VCTL responsive to enable signal EN as discussed herein.

Switching circuit 120 is an electronic circuit configured to, responsive to enable signal EN, connect the output terminal of VCO cell 130-N to the input terminal of VCO cell 130-1 when voltage source 110 is configured to output voltage VCTL having the temperature-dependent voltage level and disconnect the output terminal of VCO cell 130-N from the input terminal of VCO cell 130-1 when voltage source 110 is configured to output voltage VCTL having the predetermined voltage level.

VCO cells 130 include a total number N of VCO cells 130-1-130-N. Each VCO cell 130-1-130-N is an electronic circuit including multiple stages (not shown in FIG. 1), each stage being configured to receive voltage VCTL on voltage node VCTLN, and to execute a signal delay responsive to the voltage level of voltage VCTL.

In some embodiments, the signal delay executed by a given stage of an instance of VCO cell 130-1-130-N is configured to decrease, and a propagation speed thereby increase, as a function of increasing voltage levels of voltage VCTL. In some embodiments, the signal delay executed by a given stage of an instance of VCO cell 130-1-130-N is configured to increase, and the propagation speed thereby decrease, as a function of increasing voltage levels of voltage VCTL.

Each stage of an instance of VCO cell 130-1-130-N is configured to receive a first signal, e.g., signal OSC on feedback path FDBK, an internal signal output from another stage of the same instance of VCO cell 130-1-130-N, or an external signal output from another stage of another instance of VCO cell 130-1-130-N, and to output, responsive to the first signal and to the voltage level of voltage VCTL, a second signal, e.g., signal OSC on feedback path FDBK, an internal signal to another stage of the same instance of VCO cell 130-1-130-N, or an external signal to another stage of another instance of VCO cell 130-1-130-N.

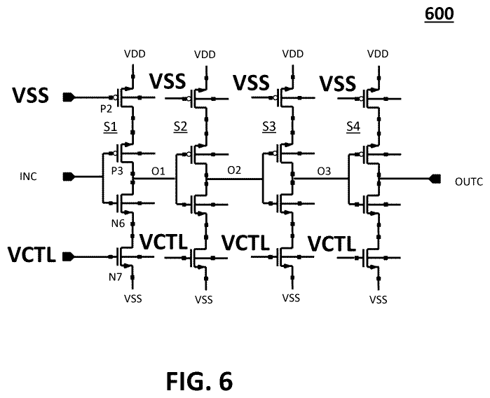

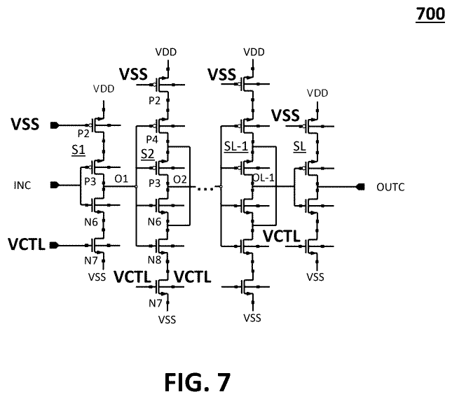

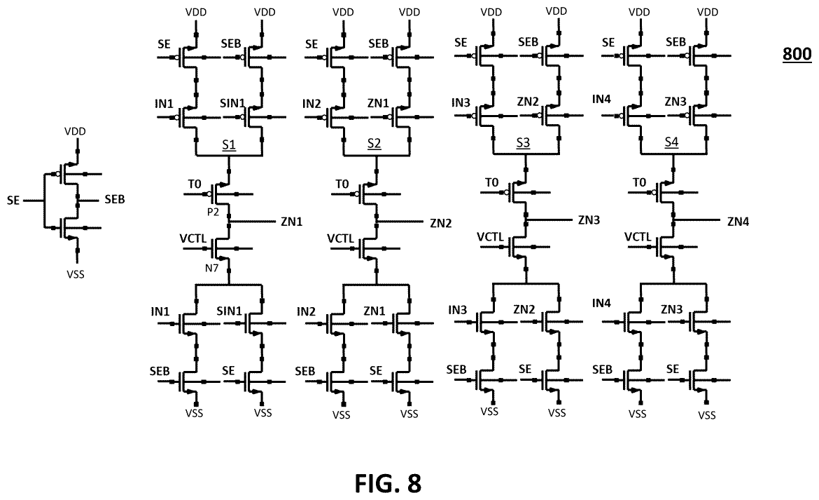

In various embodiments, one or more instances of VCO cell 130-1-130-N includes one of VCO cells 200A-200C discussed below with respect to FIGS. 2A-2C, VCO cells 300A-300C discussed below with respect to FIGS. 3A-3E, a VCO cell 600 discussed below with respect to FIG. 6, a VCO cell 700 discussed below with respect to FIG. 7, or a VCO cell 800 discussed below with respect to FIG. 8.

As the total number N of VCO cells 130 increases, an area occupied by VCO cells 130 increases, thereby increasing an overall area occupied by IC 100. In some embodiments, IC 100 includes VCO cells 130 having the number N less than or equal to ten. In some embodiments, IC 100 includes VCO cells 130 having the number N equal to one, two, three, four, five, six, or seven.

The series arrangement of buffers 140 and 150 is configured to receive oscillation signal OSC from feedback path FDBK and output signal FOUT on output node OUT. In various embodiments, buffers 140 and 150 are configured to output signal FOUT in phase with or complementary to oscillation signal OSC.

A buffer, e.g., buffer 140 and/or 150, is an electronic circuit including an input terminal (not labeled) configured to have a high input impedance, thereby minimizing loading of an adjacent circuit, e.g., the output terminal of VCO cell 130-N or buffer 140, and an output terminal (not labeled) configured to have a low output impedance, thereby being capable of driving an adjacent circuit, e.g., frequency measurement circuit 160 or buffer 150. In some embodiments, a buffer includes an inverter.

Frequency measurement circuit 160 is an electronic circuit configured to receive signal FOUT, detect a frequency of signal FOUT, and generate an output signal (not shown) indicative of the frequency. In some embodiments, frequency measurement circuit 160 includes a frequency counter.

In some embodiments, IC 100 does not include frequency measurement circuit 160, and buffers 140 and 150 are configured to output signal FOUT to a circuit (not shown) external to IC 100. In some embodiments, IC 100 does not include frequency measurement circuit 160 or buffers 140 and 150, and feedback path FDBK, e.g., switching circuit 120, is configured to output oscillation signal OSC to a circuit (not shown) external to IC 100.

By the configuration discussed above, IC 100 includes temperature-dependent voltage source 110 and a VCO including one or more multistage VCO cells 130-1-130-N and feedback path FDBK, and each VCO cell 130-1-130-N receives temperature-dependent voltage VCTL whereby the VCO outputs signal OSC or FOUT having a frequency indicative of the temperature of voltage source 110. Compared to approaches that are not based on multistage VCO cells, IC 100 is thereby capable of outputting signal OSC or FOUT using less area while maintaining thermal linear sensitivity.

FIGS. 2A-2C are plan views of IC layouts 200A-200C and corresponding multistage VCO cells 200A-200C, in accordance with some embodiments. Each of IC layouts/cells 200A-200C is usable as one or more of VCO cells 130-1-130-N discussed above with respect to FIG. 1.

Each of IC layouts/cells 200A-200C includes an array of stages S1-S8/S16 arranged between two instances of a dummy gate DG, also referred to as a dummy gate region DG or dummy gate structure DG in some embodiments.

Each one of stages S1-S8/S16 includes an inverter configured as discussed above with respect to VCO cells 130-1-130-N. In some embodiments, a given one of stages S1-S8/S16 includes VCO stage 500 discussed below with respect to FIG. 5.

Each inverter of a stage S1-S8/S16 includes one or more PMOS and/or NMOS transistors including various features, e.g., active regions/areas, gate regions/structures, source/drain (S/D) regions/structures, conductive regions/structures, and/or isolation regions/structures, that are not depicted or further discussed for the purpose of clarity. In various embodiments, the various features correspond to the one or more PMOS and/or NMOS transistors including field effect transistors (FETs), FinFETs, gate-all-around (GAA) transistors, or other suitable transistor types.

A gate region/structure is a region in the IC layout diagram included in the manufacturing process as part of defining a gate structure. A gate structure is a volume including one or more conductive segments, e.g., a gate electrode, including one or more conductive materials, e.g., polysilicon (poly), copper (Cu), aluminum (Al), tungsten (W), cobalt (Co), ruthenium (Ru), or one or more other metals or other suitable materials, substantially surrounded by one or more insulating materials, the one or more conductive segments thereby being configured to control a voltage provided at an adjacent gate dielectric layer.

A dielectric layer, e.g., a gate dielectric layer, is a volume including one or more insulating materials, e.g., silicon dioxide, silicon nitride (Si₃N₄), and/or one or more other suitable material such as a low-k material having a k value less than 3.8 or a high-k material having a k value greater than 3.8 such as aluminum oxide (Al₂O₃), hafnium oxide (HfO₂), tantalum pentoxide (Ta₂O₅), or titanium oxide (TiO₂), suitable for providing a high electrical resistance between IC structure elements, i.e., a resistance level above a predetermined threshold corresponding to one or more tolerance levels of a resistance-based effect on circuit performance.

In various embodiments, a gate dielectric layer has a substantially planar shape, e.g., as part of a planar transistor, a shape corresponding to a transistor topography, e.g., as part of a FinFET, or a substantially cylindrical shape, e.g., as part of a GAA transistor, whereby the gate electrode is separated from a corresponding channel region by a distance sufficiently large to limit current flow to a specified level, and sufficiently small to enable generation of an electric field in the channel having a specified field strength.

In some embodiments, in contrast to a gate region/structure that intersects/overlaps an active region/area as part of defining a transistor that includes multiple portions of the active region/area adjacent to the gate region/structure, a dummy gate region/structure is positioned over or adjacent to an edge of a gate region/area. Accordingly, only a single portion of the corresponding active region/area is adjacent to the dummy gate/region; the dummy gate is thereby external to transistors structures of the IC but capable of being adjacent to a transistor that includes the portion of the active region/area adjacent to the dummy gate region/structure.

In the embodiments depicted in FIGS. 2A-2C, gate regions/structures and dummy gate regions/structures DG extend in parallel vertically. In some embodiments, gate regions/structures and dummy gate regions/structures DG extend in parallel horizontally.

In some embodiments, the parallel gate regions/structures and dummy gate regions/structures are spaced apart at locations corresponding to a gate pitch, also referred to as a contact poly pitch (CPP) in some embodiments. In some embodiments, a minimum percentage or an entirety of the gate pitch locations include either gate or dummy gate regions/structures in accordance with loading uniformity requirements of one or more pieces of manufacturing equipment used to construct the gate/dummy gate structures corresponding to the gate/dummy gate regions.

In some embodiments, an active region/area is referred to as an oxide diffusion (OD) region/area, and a dummy gate region/structure is referred to as a continuous poly on OD edge (CPODE) region/structure.

In some embodiments, an IC layout 200A-200C includes one or more cut-gate regions that intersect one or more of dummy gate regions DG such that the corresponding dummy gate region/structure DG, e.g., as depicted in FIGS. 2A-2C, includes multiple portions that are referred to herein as a single dummy gate region/structure DG.

A cut-gate region, also referred to as a cut-poly region in some embodiments, is a region in the IC layout diagram included in the manufacturing process as part of defining a discontinuity in the gate electrode of a given gate structure, e.g., a portion etched away after the gate electrode has been deposited, thereby electrically isolating the corresponding adjacent portions of the gate electrode from each other.

As depicted in FIGS. 2A-2C, each one of stages S1-S8/S16 includes input terminals configured to receive a voltage TO, voltage VCTL discussed above with respect to FIG. 1, a signal INx (x=1..16) corresponding to the first signals discussed above with respect to VCO cells 130, and an output terminal configured to output a signal ZNx corresponding to the second signals discussed above with respect to VCO cells 130.

Voltage TO is a voltage received by each one of stages S1-S8/S16 having a voltage level corresponding to reference voltage VSS or the low logic level discussed above with respect to FIG. 1. In some embodiments, each one of stages S1-S8/S16 is configured to receive voltage TO as reference voltage VSS from a reference voltage node. In some embodiments, each one of stages S1-S8/S16 is configured to receive voltage TO as a buffered voltage from a circuit (not shown) external to VCO cell 200A-200C, e.g., a tie cell or tie low cell.

In the embodiments depicted in FIGS. 2A-2C, each one of stages S1-S8/S16 is configured to be activated, e.g., capable of signal propagation, responsive to the low logic or reference voltage level of voltage TO, and to be otherwise deactivated, e.g., configured to have a high-impedance output. In some embodiments, each one of stages S1-S8/S16 includes a PMOS transistor including a gate configured to receive voltage TO.

In some embodiments, one or more of stages S1-S8/S1-S16 is configured to be activated responsive to voltage TO having the high logic level or power supply voltage VDD, and otherwise deactivated, e.g., by including an NMOS transistor including a gate configured to receive voltage TO, e.g., from a tie (high) cell or power supply voltage node.

As depicted in FIGS. 2A-2C, IC layout/VCO cell 200A includes the array of stages S1-S8 arranged in a single row between the two instances of dummy gate region/structure DG, IC layout/VCO cell 200B includes the array of stages S1-S8 arranged in two rows between the two instances of dummy gate region/structure DG, and IC layout/VCO cell 200C includes the array of stages S1-S16 arranged in four rows between the two instances of dummy gate region/structure DG.

Each of IC layouts/VCO cells 200A-200C includes the individual stages of stages S1-S8/S16 adjacent to each other in both the row and column directions (if applicable) such that each of IC layouts/VCO cells 200A-200C is free from including an instance of dummy gate region/structure DG between the two instances of dummy gate region/structure DG depicted in the corresponding FIG. 2A-2C. In some embodiments, the two instances of dummy gate region/structure DG are included in a cell border (not shown) of the corresponding IC layout 200A-200C. In some embodiments, the two instances of dummy gate region/structure DG are referred to as border dummy gate regions/structures.

By being free from including additional instances of dummy gate region/structure DG between the border dummy gate regions/structures DG, each of IC layouts/VCO cells 200A-200C is capable of requiring less space than other approaches that include additional instances of a dummy gate region/structure, e.g., approaches in which a VCO cell includes a single stage such that each stage is separated from another stage by an instance of a border dummy gate region/structure.

The numbers of array rows and stages S1-S8/S16 depicted in FIGS. 2A-2C, and in FIGS. 3A-3C discussed below, are non-limiting examples provided for the purpose of illustration. Other numbers of array rows and stages similarly positioned between two instances of dummy gate region/structure DG are within the scope of the present disclosure.

FIGS. 3A-3E are plan views of IC layouts 300A-300C and corresponding multistage VCO circuits 300A-300C, in accordance with some embodiments. Each of IC layouts/circuits 300A-300C is usable as some or all of voltage source 110 and one or more of VCO cells 130-1-130-N discussed above with respect to FIG. 1.

Each of IC layouts/circuits 300A-300C includes stages S1-S8/S16 arranged between two border dummy gate regions/structures DG as discussed above with respect to FIGS. 2A-2C. Compared to IC layouts/VCO cells 200A-200C, each of IC layouts/circuits 300A-300C also includes voltage source 110 and additional instances of dummy gate region/structure DG positioned between the two border dummy gate regions/structures DG.

In the embodiments depicted in FIGS. 3A-3C, each of IC layouts/circuits 300A-300C includes voltage source 110 and two additional instances of dummy gate region/structure DG positioned between first and second portions of stages S1-S8/S16. Voltage source 110 is separated from each of the first and second portions by single instances of dummy gate region/structure DG, and each of the first and second portions includes half of the total number of stages S1-S8/S16.

At least one of the first or second portion of stages S1-S8/S16 includes more than one stage, and each of the first and second portions of stages S1-S8/S16 is free from including an instance of dummy gate region/structure DG. In some embodiments, the first and second portions include numbers other than half the total number of stages S1-S8/S16.

In the embodiments depicted in FIGS. 3B and 3C, each of IC layouts/circuits 300B and 300C includes voltage source 110 separated from each of the first and second portions by dummy gate region/structure DG extending across each of multiple rows of stages S1-S8/S16. In some embodiments, voltage source 110 is separated from the first and second portions by instances of dummy gate region/structure DG that extend across a subset of the multiple rows of stages S1-S8/S16, e.g., based on a third portion of stages S1-S8/S16 extending continuously between the two border dummy gate regions/structures.

Compared to IC layouts/circuits 200A-200C in which voltage VCTL is received from a source, e.g., voltage source 110, positioned outside of the two border dummy gate regions/structures DG, IC layouts/circuits 300A-300C including voltage source 110 positioned between the two border dummy gate regions/structures DG enable increased uniformity of parasitic effects, e.g., resistance-capacitance (RC) impacts, and reduced variation of voltage levels of voltage VCTL across an IC or IC die. Because of the two additional instances of dummy gate region/structure DG, a tradeoff of this performance enhancement is a reduction of the improvement in circuit area requirements discussed above with respect to IC layouts/circuits 200A-200C.

Each of FIGS. 3D and 3E depicts an embodiment in which voltage source 110 is separated from a given portion of stages S1-S8/S16 by more than one additional instance of dummy gate region/structure DG. FIG. 3D depicts an embodiment in which the additional instances of dummy gate region/structure DG are included in voltage source 110, and FIG. 3E depicts an embodiment in which the additional instances of dummy gate region/structure DG are included in the given portion of stages S1-S8/S16.

Compared to the embodiments depicted in FIGS. 3A-3C, the embodiments depicted in FIGS. 3D and 3E enable reductions in IC processing dependent (ICD) effects, e.g., uncertainty in the voltage levels of voltage VCTL, based on voltage source 110 being separated from a given portion of stages S1-S8/S16 by an increased distance by the more than one additional instance of dummy gate region/structure DG. Because of the additional instances of dummy gate region/structure DG, a tradeoff of this performance enhancement is a further reduction of the improvement in circuit area requirements discussed above with respect to IC layouts/circuits 200A-200C.

In each of the embodiments depicted in FIGS. 3D and 3E, a total of two instances of dummy gate region/structure DG separate voltage source 110 from the given portion of stages S1-S8/S16 and are separated from each other by a multiple of the gate pitch xGP. In some embodiments, the two instances of gate region/structure DG are separated from each other by more than two instances of gate region/structure DG positioned at locations corresponding to the gate pitch, and the outermost instances of the instances of gate region/structure DG are separated from each other by the multiple of the gate pitch xGP.

As the number of multiples x of the gate pitch GP increases, the reduction in ICD effects increases at the expense of further reductions in circuit area improvements. In some embodiments, the two instances of gate region/structure DG are separated from each other by a gate pitch multiple ranging from three to eight. In some embodiments, the two instances of gate region/structure DG are separated from each other by a gate pitch multiple equal to seven.

FIG. 4 is a schematic diagram of voltage source 400, in accordance with some embodiments. Voltage source 400 is usable as voltage source 110 discussed above with respect to FIGS. 1-3E.

Voltage source 400 includes a first branch (not labeled) including NMOS transistors N1 and N2 and a second branch 9Not labeled) including a PMOS transistor P1 and NMOS transistors N3-N5. NMOS transistors N1 and N2 are coupled in series between a gate of PMOS transistor P1 and reference voltage node/reference voltage VSS, with NMOS transistor N1 configured as a diode and NMOS transistor N2 including a gate configured to receive enable signal EN. PMOS transistor and NMOS transistors N3-N5 are coupled in series between power supply voltage node/power supply voltage VDD and reference voltage node/reference voltage VSS, with PMOS transistor P1 configured as a diode and each of NMOS transistors N3-N5 including a gate configured to receive enable signal EN. An output terminal Z is positioned between NMOS transistors N3 and N₄ and coupled to voltage node VCTLN discussed above.

Voltage source 400 is thereby configured to, in operation, respond to enable signal EN having the high logic level by switching on each of NMOS transistors N2-N5, thereby causing current to flow through each of the first and second branches, and to respond to enable signal EN having the low logic level by switching off each of NMOS transistors N2-N5, thereby restricting current flow.

Current flow through each the first and second branches causes a current to flow through the series connection of PMOS transistor P1 and NMOS transistor N1. Based on the diode configurations of PMOS transistor P1 and NMOS transistor N1, the current flow generates a temperature-dependent voltage drop across PMOS transistor P1. A difference between power supply voltage VDD and this voltage drop appears across NMOS transistors N3-N5 which act to divide the difference to produce voltage VCTL on output terminal Z.

Voltage source 400 is thereby configured to output voltage VCTL on voltage node VCTLN having voltage levels that increase with increasing temperatures such that a circuit, e.g., IC 100, including voltage source 400 is capable of realizing the benefits discussed above.

FIG. 5 is a schematic diagram of VCO stage 500, in accordance with some embodiments. VCO stage 500 is usable as a stage, e.g., one of stages S1-S8/S16, of multistage VCO cells 130 discussed above with respect to FIGS. 1-3E.

VCO stage 500 includes PMOS transistors P2 and P3 coupled in series with NMOS transistors N6 and N7 between power supply voltage node/power supply voltage VDD and reference voltage node/reference voltage VSS. PMOS transistor P2 includes a gate configured to receive voltage TO, transistors P3 and N6 include gates coupled to an input terminal INS configured to receive the first signal, and NMOS transistor N7 includes a gate configured to receive voltage VCTL, each discussed above with respect to FIGS. 1-3E. An output terminal ZNS is positioned between PMOS transistor P3 and NMOS transistor N6 and configured to output the second signal discussed above with respect to FIGS. 1-3E.

VCO stage 500 is thereby configured to, in operation, switch on PMOS transistor P2 in response to voltage TO having the low logic level or reference voltage VSS, and cause NMOS transistor N7 to have a transconductance based on the voltage level of voltage VCTL. Transistors P3 and N6 receive the first signal on input terminal INS and invert and propagate the first signal as the second signal on output terminal ZNS. A speed at which transistors P3 and N6 propagate the inverted first signal is controlled by the transconductance of NMOS transistor N7.

VCO stage 500 is thereby configured to output the second signal based on the first signal at a speed that increases as the voltage level of voltage VCTL increases such that a circuit, e.g., IC 100, including VCO stage 500 is capable of realizing the benefits discussed above.

FIGS. 6 and 7 are schematic diagrams of respective VCO cells 600 and 700, in accordance with some embodiments. Each of VCO cells 600 and 700 is usable as one or more of VCO cells 130-1-130-N discussed above with respect to FIGS. 1-3E. In some embodiments, one or both of VCO cells 600 or 700 is referred to as a delay cell 600 or 700, a VCO delay cell 600 or 700, or a multistage VCO cell 600 or 700.

In the embodiments depicted in FIGS. 6 and 7, VCO cells 600 and 700 include four stages S1-S4 and a number L of stages S1-SL, respectively, coupled in series between an input terminal INC and an output terminal OUTC, each stage including transistors P2, P3, N6, and N7 (a single stage S1 labeled for the purpose of clarity) configured as discussed above with respect to FIG. 5. Other numbers of stages are within the scope of the present disclosure.

Each of VCO cells 600 and 700 is thereby configured to, in operation, receive the first signal of stage S1 at input terminal INC from a source external to VCO cell 600 or 700, e.g., as a signal output from another instance of VCO cell 600 or 700, or as oscillation OSC on feedback path FDBK discussed above. Stage S1 inverts and propagates the first signal as the second signal being an internal signal O1 corresponding to the first signal of stage S2. In turn, successive stages S2-S4/SL-1 invert and propagate the corresponding first and second signals as internal signals O2, O3, and in the case of VCO cell 700, OL-1. The last stage S4 or SL inverts and propagates the first signal being signal O3 or OL-1 as the second signal eternal to VCO 600 or 700 on output terminal OUTC, e.g., to another instance of VCO cell 600 or 700 or as oscillation signal OSC on feedback path FDBK discussed above.

As depicted in FIG. 7, VCO cell 700 includes each of stages S2-SL-1 also including a PMOS transistor P4 coupled between PMOS transistors P2 and P3 and an NMOS transistor N8 coupled between NMOS transistors N6 and N7. Each of transistors P4 and N8 includes a gate coupled to the gates of transistors P3 and N6 and is thereby configured to receive the first signal discussed above. Drain terminals of each of transistors P4 and N8 are coupled to each other and to source terminals of each of transistors P3 and N6.

Compared to stages S1 and SL, stages S2-SL-1 are thereby configured to, in operation, propagate the first signal having a greater delay, and thereby slower speed, for a given voltage level of voltage VCTL. In some embodiments, stages S2-SL-1 are referred to as internal stages S2-SL-1.

In some embodiments, one or both of VCO cell 600 or 700 is configured in accordance with the embodiments discussed above with respect to FIGS. 2A-3E, e.g., as an array of stages positioned between two instances of dummy gate region/structure DG.

Each of VCO cells 600 and 700 is thereby configured to include multiple stages S1-S4/SL configured to receive voltage VCTL on voltage node VCTLN, and to execute a signal propagation delay responsive to the voltage level of voltage VCTL such that a circuit, e.g., IC 100, including VCO cell 600 or 700 is capable of realizing the benefits discussed above.

As a number of stages, e.g. stages S1-S4 of VCO cell 600 or stages S1-SL of VCO cell 700 including internal stages S2-SL-1, increases, a total signal propagation delay increases and an oscillation frequency decreases. In some embodiments, VCO cell 600 or 700 includes a total number of stages ranging from two to twelve. In some embodiments, VCO cell 600 or 700 includes a total number of stages equal to four, six, or eight.

In first through third non-limiting examples, embodiments of IC 100 include a single VCO cell 130 (N=1) corresponding to VCO cell 600 including a total of four stages and VCO cell 700 including totals of four and eight stages, respectively. Compared to an approach in which a VCO circuit includes 20 single-stage VCO cells, a circuit area is reduced from 100% to 38%, 39%, and 35%, respectively, and thermal linear sensitivity is maintained or increased.

In fourth through eighth non-limiting examples, embodiments of IC 100 include each of VCO cells 130-1-130-7 corresponding to four-stage VCO cells 600, each of VCO cells 130-1-130-5 corresponding to four-stage VCO cells 700, VCO cells 130-1-130-3 corresponding to one four-stage VCO cell 600 and two six-stage VCO cells 700, and each of VCO cells 130-1-130-2 corresponding to eight-stage VCO cells 700, respectively. Compared to an approach in which a VCO circuit includes 32 single-stage VCO cells, a circuit area is reduced from 100% to 32%, 29%, 25%, and 26%, respectively, and thermal linear sensitivity is maintained.

FIG. 8 is a schematic diagram of multibit VCO cell 800, in accordance with some embodiments. VCO cell 800, also referred to as multistage VCO cell 800 or multibit VCO cell 800 in some embodiments, is usable as one or more of VCO cells 130-1-130-N discussed above with respect to FIGS. 1-3E, in embodiments in which VCO cells 130-1-130-N and feedback path DFBK, including switching circuit 120, are configured to include multiple signal paths.

In the embodiment depicted in FIG. 8, VCO cell 800 includes stages S1-S4, each of which includes PMOS transistor P2 configured to receive voltage TO and NMOS transistor N7 configured to receive voltage VCTL, coupled in series between power supply voltage node VDD and reference voltage node VSS as discussed above with respect to FIGS. 6 and 7. VCO cell 800 also includes an inverter (not labeled) configured to receive a select signal SE and output a complementary select signal SEB.

Each stage S1-S4 of VCO cell 800 also includes first and second branches of two PMOS transistors (not labeled) coupled between power supply voltage node VDD and transistor P2, and first and second branches of two NMOS transistors (not labeled) coupled between transistor N7 and reference voltage node VSS.

The PMOS transistors of the first branches of stages S1-S4 are configured to receive select signal SE and respective signals IN1-IN4, and the NMOS transistors of the first branches of stages S1-S4 are configured to receive select signal SEB and respective signals IN1-IN4. The PMOS transistors of the second branches of stages S1-S4 are configured to receive select signal SEB and respective signals SIN1 (from a source external to VCO cell 800) and ZN1-ZN3, and the NMOS transistors of the second branches of stages S1-S4 are configured to receive select signal SE and respective signals SIN1 and ZN1-ZN3.

Each stage S1-S4 of VCO cell 800 is thereby configured to, in operation, alternatively switch the corresponding instances of transistors P2 and N7 between the first and second branches by outputting corresponding signals ZN1-ZN4 in response to corresponding signals IN1-IN4 when select signal SE has the low logic level, and outputting corresponding signals ZN1-ZN4 in response to corresponding signals SIN1 and ZN1-ZN3 when select signal SE has the high logic level.

VCO cell 800 is thereby configured to, in operation, respond to the high and low logic levels of select signal SE by alternatively inverting and propagating signals SIN1 and ZN1-ZN3 or signals IN1-IN4, and to execute a signal propagation delay responsive to the voltage level of voltage VCTL received on voltage node VCTLN such that a circuit, e.g., IC 100 or 900, including VCO stage 800 is capable of realizing the benefits discussed above.

The numbers of stages and signals depicted in FIG. 8 are non-limiting examples provided for the purpose of illustration. VCO cell 800 including other numbers of stages and signals is within the scope of the present disclosure.

FIG. 9 is a schematic diagram of an IC 900, in accordance with some embodiments. IC 900 corresponds to an embodiment of IC 100 discussed above in which multistage VCO cells 130-1-130-N correspond to instances of multibit VCO cell 800 discussed below with respect to FIG. 8. Compared to IC 100, IC 900 does not include voltage source 110, and VCO cell 130-1 includes a circuit component (not shown) configured to output voltage VCTL responsive to enable signal EN.

FIG. 9 depicts a non-limiting example of IC 900 in which VCO cell 130-1 includes a 16-bit VCO cell 800 and VCO cells 130-2-130-N include eight-bit VCO cells 800. Other numbers of VCO cells 130 including other bit numbers are within the scope of the present disclosure.

In a non-limiting example, an embodiment of IC 100 or 900 includes VCO cell 130-1 corresponding to a 16-bit VCO cell 800 and each of VCO cells 130-2 and 130-3 corresponding to eight-bit VCO cells 800. Compared to an approach in which a VCO circuit includes 32 single-stage VCO cells, a circuit area is reduced from 100% to 46%, thermal linear sensitivity is maintained, and routing resources associated with voltages TO and VCTL are saved.

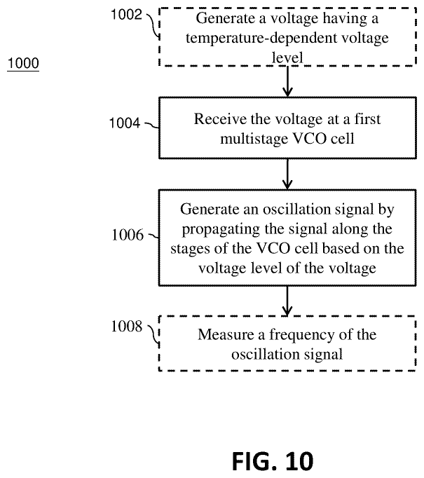

FIG. 10 is a flowchart of a method 1000 of operating an IC, in accordance with some embodiments. Method 1000 is capable of being performed on an IC, e.g., IC 100 or 900 discussed above with respect to FIGS. 1-9.

In some embodiments, performing some or all of the operations of method 1000 is part of obtaining a temperature variation map and/or performing a signoff operation on a manufacturing process.

The sequence in which the operations of method 1000 are depicted in FIG. 10 is for illustration only; the operations of method 1000 are capable of being executed simultaneously or in sequences that differ from that depicted in FIG. 10. In some embodiments, operations in addition to those depicted in FIG. 10 are performed before, between, during, and/or after the operations depicted in FIG. 10.

At operation 1002, in some embodiments, a voltage having a temperature-dependent voltage level is generated. In some embodiments, generating the voltage includes using a voltage source. In some embodiments, generating the voltage includes using voltage source 110 discussed above with respect to FIGS. 1-9.

In some embodiments, generating the voltage includes using a component of a VCO cell, e.g., VCO cell 130-1 discussed above with respect to FIGS. 1-9.

In some embodiments, generating the voltage includes generating the voltage in response to an enable signal, e.g., enable signal EN discussed above with respect to FIGS. 1-9.

At operation 1004, the voltage is received at a first multistage VCO cell. In some embodiments, receiving the voltage includes receiving the voltage from a source external to the IC. In some embodiments, receiving the voltage includes receiving the voltage from a source internal to the IC, e.g., voltage source 110 or VCO cell 130-1 discussed above with respect to FIGS. 1-9.

In some embodiments, receiving the voltage at the first multistage VCO cell includes receiving the voltage at VCO cell 130-1, 200A-200C, 300A-300C, or 600-800 discussed above with respect to FIGS. 1-9.

Receiving the voltage at the first multistage VCO cell includes receiving the voltage at each stage of the VCO cell, e.g., each of stages S1-S4/S8/S16 discussed above with respect to FIGS. 1-9.

In some embodiments, receiving the voltage at the first multistage VCO cell includes receiving the voltage at a plurality of multistage VCO cells, e.g., VCO cells 130 discussed above with respect to FIGS. 1-9.

At operation 906, an oscillation signal is generated by propagating the signal along the stages of the VCO cell based on the voltage level of the voltage. In some embodiments, generating the oscillation signal includes generating signal OSC or FOUT discussed above with respect to FIGS. 1-9.

In some embodiments, propagating the signal along the stages of the VCO cell includes propagating the signal along stages S1-S4/S8/S16 of VCO cell 130-1, 200A-200C, 300A-300C, or 600-800 discussed above with respect to FIGS. 1-9.

In some embodiments, propagating the signal along the stages of the VCO cell based on the voltage level of the voltage includes propagating the signal based on the voltage level of voltage VCTL discussed above with respect to FIGS. 1-9.

At operation 1008, in some embodiments, a frequency of the oscillation signal is measured. In some embodiments, measuring the frequency of the oscillation signal includes using a circuit or device external to the IC. In some embodiments, measuring the frequency of the oscillation signal includes using a circuit internal to the IC, e.g., frequency measurement circuit 160 discussed above with respect to FIGS. 1-9.

By executing some or all of the operations of method 1000, an oscillation signal having a temperature-dependent frequency is generated using a multistage VCO cell, thereby enabling the realization of the benefits discussed above with respect to ICs 100 and 900.

FIG. 11 is a flowchart of a method 1100 of manufacturing an IC, in accordance with some embodiments. Method 1100 is operable to form some or all of IC 100 or 900 discussed above with respect to FIGS. 1-9.

In some embodiments, performing some or all of the operations of method 1100 is part of building a plurality of IC devices, e.g., transistors, logic gates, memory cells, interconnect structures, and/or other suitable devices, by performing a plurality of manufacturing operations, e.g., one or more of a lithography, diffusion, deposition, etching, planarizing, or other operation suitable for building the plurality of IC devices in a semiconductor wafer.

In some embodiments, the operations of method 1100 are performed in the order depicted in FIG. 11. In some embodiments, the operations of method 1100 are performed in an order other than the order depicted in FIG. 11. In some embodiments, one or more additional operations are performed before, during, and/or after the operations of method 1100. In some embodiments, performing some or all of the operations of method 1100 includes performing one or more operations as discussed below with respect to IC manufacturing system 1400 and FIG. 14.

At operation 1102, in some embodiments, a plurality of transistor features is formed in a semiconductor substrate. In some embodiments, forming the plurality of transistor features includes forming the transistor features corresponding to one or more instances of IC 100 or 900, discussed above with respect to FIGS. 1-9.

In some embodiments, forming the plurality of transistor features includes performing one or more deposition and/or implantation processes in areas of a semiconductor substrate corresponding to the one or more instances of IC 100 or 900. In some embodiments, forming the first and second epitaxial regions includes forming active areas and S/D structures.

At operation 1104, a plurality of gate structures is constructed on the plurality of transistor features, thereby forming multiple stages of a VCO cell between first and second dummy gate structures. Forming the multiple stages of the VCO cell between the first and second dummy gate structures includes forming stages S1-S4/S8/S16 of VCO cell 130, 200A-200C, 300A-300C, or 600-800 between dummy gate structures DG, discussed above with respect to FIGS. 1-9.

In some embodiments, constructing the plurality of gate structures includes forming one or more circuits in addition to the VCO cell, e.g., one or more additional VCO cells 130-1-130-N and/or one or more of voltage source 110, switching circuit 120, buffers 140 and 150, or frequency measurement circuit 160 discussed above with respect to FIGS. 1-9.

In some embodiments, constructing the plurality of gate structures includes performing a plurality of manufacturing operations, e.g., one or more of a lithography, diffusion, deposition, etching, planarizing, or other operation suitable for constructing the plurality of gate structures as discussed above with respect to FIGS. 1-9.

At operation 1106, electrical connections including a feedback path and connections to a temperature-dependent voltage source are formed, thereby forming a VCO. In some embodiments, forming the electrical connections includes forming feedback path FDBK and connections to voltage source 110 discussed above with respect to FIGS. 1-9.

In some embodiments, forming the VCO includes forming voltage source 110 or a voltage source component, switching circuit 120, VCO cells 130, and in some embodiments buffers 140 and 150, each discussed above with respect to FIGS. 1-9.

In some embodiments, forming the electrical connections includes forming one or more via structures and/or metal segments by performing a plurality of manufacturing operations including depositing and patterning one or more photoresist layers, performing one or more etching processes, and performing one or more deposition processes whereby one or more conductive materials are configured to form a continuous, low resistance structure.

At operation 1108, in some embodiments, electrical connections are formed from the VCO to the frequency measurement circuit. In some embodiments, forming the electrical connections from the VCO to the frequency measurement circuit includes forming the electrical connections to the frequency measurement circuit external to the IC. In some embodiments, forming the electrical connections from the VCO to the frequency measurement circuit includes forming the electrical connections to frequency measurement circuit 160 discussed above with respect to FIGS. 1-9.

By performing some or all of the operations of method 1100, an IC is manufactured in which a VCO includes one or more multistage VCO cells configured to generate an oscillation signal having a temperature-dependent frequency, thereby enabling the realization of the benefits discussed above with respect to ICs 100 and 900.

FIG. 12 is a flowchart of a method 1200 of generating an IC layout diagram, e.g., an IC layout diagram 200A-200C discussed above with respect to FIGS. 2A-2C or IC layout diagram 300A-300C discussed above with respect to FIGS. 3A-3E, in accordance with some embodiments.

In some embodiments, generating the IC layout diagram includes generating the IC layout diagram corresponding to an IC, e.g., IC device 100 or 900 discussed above with respect to FIGS. 1-9, manufactured based on the generated IC layout diagram.

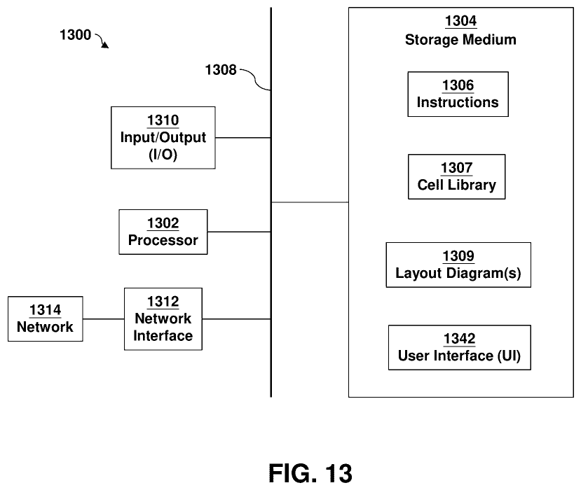

In some embodiments, some or all of method 1200 is executed by a processor of a computer, e.g., a processor 1302 of an IC layout diagram generation system 1300, discussed below with respect to FIG. 13.

Some or all of the operations of method 1200 are capable of being performed as part of a design procedure performed in a design house, e.g., a design house 1420 discussed below with respect to FIG. 14.

In some embodiments, the operations of method 1200 are performed in the order depicted in FIG. 12. In some embodiments, the operations of method 1200 are performed simultaneously and/or in an order other than the order depicted in FIG. 12. In some embodiments, one or more operations are performed before, between, during, and/or after performing one or more operations of method 1200.

At operation 1202, one or more multistage VCO cells are arranged in an IC layout diagram. Arranging the one or more multistage VCO cells includes arranging one or more of VCO cells 130, 200A-200C, 300A-300C, or 600-800 discussed above with respect to FIGS. 1-9.

In some embodiments, arranging the one or more VCO cells includes arranging an array of stages, e.g., stages S1-S8/S16 of VCO cells 200A-200C or 300A-300C as discussed above with respect to FIGS. 2A-3E.

In some embodiments, arranging the one or more VCO cells includes obtaining the one or more VCO cells from a cell library, e.g., cell library 1307 of IC layout diagram generation system 1300, discussed below with respect to FIG. 13.

In some embodiments, arranging the one or more VCO cells includes storing one or more modified IC layout diagrams of the one or more VCO cells in a cell library, e.g., cell library 1307 of IC layout diagram generation system 1300.

At operation 1204, electrical connections from a temperature dependent voltage source to each stage of the VCO cell are configured in the IC layout diagram. In some embodiments, configuring the electrical connections from a temperature dependent voltage source to each stage of the VCO cell includes configuring voltage node VCTLN from voltage source 110 to each stage of the VCO cell 130, 200A-200C, 300A-300C, or 600-800 discussed above with respect to FIGS. 1-9.

In some embodiments, configuring the electrical connections includes configuring additional electrical connections, e.g., configuring some or all of feedback path DFBK, connections to and/or between additional VCO cells 130, to buffers 140 and 150, and/or to a frequency measurement circuit such as frequency measurement circuit 160.

At operation 1106, in some embodiments, the IC layout diagram including the multistage VCO cell is stored in a storage device. In some embodiments, storing the IC layout diagram in the storage device includes storing IC layout 200A-200C, 300A-300C, and/or 600-800, discussed above with respect to FIGS. 1-9, in the storage device.

In various embodiments, storing the IC layout diagram in the storage device includes storing the IC layout diagram in a non-volatile, computer-readable memory or a cell library, e.g., a database, and/or includes storing the IC layout diagram over a network. In some embodiments, storing the IC layout diagram in the storage device includes storing the IC layout diagram in layout diagrams 1309 or over network 1314 of IC layout diagram generation system 1300, discussed below with respect to FIG. 13.

At operation 1208, in some embodiments, one or more manufacturing operations are performed based on the IC layout diagram. In some embodiments, performing one or more manufacturing operations includes performing one or more lithographic exposures based on the IC layout diagram. Performing one or more manufacturing operations, e.g., one or more lithographic exposures, based on the IC layout diagram is discussed above with respect to FIG. 11 and below with respect to FIG. 14.

By executing some or all of the operations of method 1200, an IC layout diagram is generated corresponding to an IC device in which a VCO includes one or more multistage VCO cells configured to generate an oscillation signal having a temperature-dependent frequency, thereby enabling the realization of the benefits discussed above with respect to ICs 100 and 900.

FIG. 13 is a block diagram of IC layout diagram generation system 1300, in accordance with some embodiments. Methods described herein of designing IC layout diagrams in accordance with one or more embodiments are implementable, for example, using IC layout diagram generation system 1300, in accordance with some embodiments.

In some embodiments, IC layout diagram generation system 1300 is a general purpose computing device including a hardware processor 1302 and a non-transitory, computer-readable storage medium 1304. Storage medium 1304, amongst other things, is encoded with, i.e., stores, computer program code 1306, i.e., a set of executable instructions. Execution of instructions 1306 by hardware processor 1302 represents (at least in part) an electronic design automation (EDA) tool which implements a portion or all of a method, e.g., method 500 of generating an IC layout diagram described above with respect to FIG. 5 and/or method 700 of generating an IC layout diagram described above with respect to FIG. 7 (hereinafter, the noted processes and/or methods).

Processor 1302 is electrically coupled to computer-readable storage medium 1304 via a bus 1308. Processor 1302 is also electrically coupled to an I/O interface 1310 by bus 1308. A network interface 1312 is also electrically connected to processor 1302 via bus 1308. Network interface 1312 is connected to a network 1314, so that processor 1302 and computer-readable storage medium 1304 are capable of connecting to external elements via network 1314. Processor 1302 is configured to execute computer program code 1306 encoded in computer-readable storage medium 1304 in order to cause IC layout diagram generation system 1300 to be usable for performing a portion or all of the noted processes and/or methods. In one or more embodiments, processor 1302 is a central processing unit (CPU), a multi-processor, a distributed processing system, an application specific integrated circuit (ASIC), and/or a suitable processing unit.

In one or more embodiments, computer-readable storage medium 1304 is an electronic, magnetic, optical, electromagnetic, infrared, and/or a semiconductor system (or apparatus or device). For example, computer-readable storage medium 1304 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1304 includes a compact disk-read only memory (CD-ROM), a compact disk-read/write (CD-R/W), and/or a digital video disc (DVD).

In one or more embodiments, computer-readable storage medium 1304 stores computer program code 1306 configured to cause IC layout diagram generation system 1300 (where such execution represents (at least in part) the EDA tool) to be usable for performing a portion or all of the noted processes and/or methods. In one or more embodiments, computer-readable storage medium 1304 also stores information which facilitates performing a portion or all of the noted processes and/or methods.

In one or more embodiments, computer-readable storage medium 1304 stores cell library 1307 of cells including such cells as disclosed herein, e.g., VCO cells 130, 200A-200C, 300A-300C, and 600-800 discussed above with respect to FIGS. 1-8.

In one or more embodiments, computer-readable storage medium 1304 stores layout diagrams 1309 including such IC layout diagrams as disclosed herein.

IC layout diagram generation system 1300 includes I/O interface 1310. I/O interface 1310 is coupled to external circuitry. In one or more embodiments, I/O interface 1310 includes a keyboard, keypad, mouse, trackball, trackpad, touchscreen, and/or cursor direction keys for communicating information and commands to processor 1302.

IC layout diagram generation system 1300 also includes network interface 1312 coupled to processor 1302. Network interface 1312 allows system 1300 to communicate with network 1314, to which one or more other computer systems are connected. Network interface 1312 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more IC layout diagram generation systems 1300.

IC layout diagram generation system 1300 is configured to receive information through I/O interface 1310. The information received through I/O interface 1310 includes one or more of instructions, data, design rules, libraries of standard cells, and/or other parameters for processing by processor 1302. The information is transferred to processor 1302 via bus 1308. IC layout diagram generation system 1300 is configured to receive information related to a UI through I/O interface 1310. The information is stored in computer-readable medium 1304 as user interface (UI) 1342.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by IC layout diagram generation system 1300. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 14 is a block diagram of IC manufacturing system 1400, and an IC manufacturing flow associated therewith, in accordance with some embodiments. In some embodiments, based on an IC layout diagram, at least one of (A) one or more semiconductor masks or (B) at least one component in a layer of a semiconductor integrated circuit is fabricated using manufacturing system 1400.

In FIG. 14, IC manufacturing system 1400 includes entities, such as a design house 1420, a mask house 1430, and an IC manufacturer/fabricator (“fab”) 1450, that interact with one another in the design, development, and manufacturing cycles and/or services related to manufacturing an IC device 1460. The entities in system 1400 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1420, mask house 1430, and IC fab 1450 is owned by a single larger company. In some embodiments, two or more of design house 1420, mask house 1430, and IC fab 1450 coexist in a common facility and use common resources.

Design house (or design team) 1420 generates an IC design layout diagram 1422. IC design layout diagram 1422 includes various geometrical patterns, e.g., a VCO cell 130, 200A-200C, 300A-300C, and/or 600-800 discussed above with respect to FIGS. 1-8. The geometrical patterns correspond to patterns of metal, oxide, or semiconductor layers that make up the various components of IC device 1460 to be fabricated. The various layers combine to form various IC features. For example, a portion of IC design layout diagram 1422 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1420 implements a proper design procedure to form IC design layout diagram 1422. The design procedure includes one or more of logic design, physical design or place and route. IC design layout diagram 1422 is presented in one or more data files having information of the geometrical patterns. For example, IC design layout diagram 1422 can be expressed in a GDSII file format or DFII file format.

Mask house 1430 includes data preparation 1432 and mask fabrication 1444. Mask house 1430 uses IC design layout diagram 1422 to manufacture one or more masks 1445 to be used for fabricating the various layers of IC device 1460 according to IC design layout diagram 1422. Mask house 1430 performs mask data preparation 1432, where IC design layout diagram 1422 is translated into a representative data file (RDF). Mask data preparation 1432 provides the RDF to mask fabrication 1444. Mask fabrication 1444 includes a mask writer. A mask writer converts the RDF to an image on a substrate, such as a mask (reticle) 1445 or a semiconductor wafer 1453. The design layout diagram 1422 is manipulated by mask data preparation 1432 to comply with particular characteristics of the mask writer and/or requirements of IC fab 1450. In FIG. 14, mask data preparation 1432 and mask fabrication 1444 are illustrated as separate elements. In some embodiments, mask data preparation 1432 and mask fabrication 1444 can be collectively referred to as mask data preparation.

In some embodiments, mask data preparation 1432 includes optical proximity correction (OPC) which uses lithography enhancement techniques to compensate for image errors, such as those that can arise from diffraction, interference, other process effects and the like. OPC adjusts IC design layout diagram 1422. In some embodiments, mask data preparation 1432 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1432 includes a mask rule checker (MRC) that checks the IC design layout diagram 1422 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1422 to compensate for limitations during mask fabrication 1444, which may undo part of the modifications performed by OPC in order to meet mask creation rules.

In some embodiments, mask data preparation 1432 includes lithography process checking (LPC) that simulates processing that will be implemented by IC fab 1450 to fabricate IC device 1460. LPC simulates this processing based on IC design layout diagram 1422 to create a simulated manufactured device, such as IC device 1460. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1422.

It should be understood that the above description of mask data preparation 1432 has been simplified for the purposes of clarity. In some embodiments, data preparation 1432 includes additional features such as a logic operation (LOP) to modify the IC design layout diagram 1422 according to manufacturing rules. Additionally, the processes applied to IC design layout diagram 1422 during data preparation 1432 may be executed in a variety of different orders.

After mask data preparation 1432 and during mask fabrication 1444, a mask 1445 or a group of masks 1445 are fabricated based on the modified IC design layout diagram 1422. In some embodiments, mask fabrication 1444 includes performing one or more lithographic exposures based on IC design layout diagram 1422. In some embodiments, an electron-beam (e-beam) or a mechanism of multiple e-beams is used to form a pattern on a mask (photomask or reticle) 1445 based on the modified IC design layout diagram 1422. Mask 1445 can be formed in various technologies. In some embodiments, mask 1445 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 1445 includes a transparent substrate (e.g., fused quartz) and an opaque material (e.g., chromium) coated in the opaque regions of the binary mask. In another example, mask 1445 is formed using a phase shift technology. In a phase shift mask (PSM) version of mask 1445, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1444 is used in a variety of processes. For example, such a mask(s) is used in an ion implantation process to form various doped regions in semiconductor wafer 1453, in an etching process to form various etching regions in semiconductor wafer 1453, and/or in other suitable processes.

IC fab 1450 is an IC fabrication business that includes one or more manufacturing facilities for the fabrication of a variety of different IC products. In some embodiments, IC Fab 1450 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1450 includes wafer fabrication tools 1452 configured to execute various manufacturing operations on semiconductor wafer 1453 such that IC device 1460 is fabricated in accordance with the mask(s), e.g., mask 1445. In various embodiments, fabrication tools 1452 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1450 uses mask(s) 1445 fabricated by mask house 1430 to fabricate IC device 1460. Thus, IC fab 1450 at least indirectly uses IC design layout diagram 1422 to fabricate IC device 1460. In some embodiments, semiconductor wafer 1453 is fabricated by IC fab 1450 using mask(s) 1445 to form IC device 1460. In some embodiments, the IC fabrication includes performing one or more lithographic exposures based at least indirectly on IC design layout diagram 1422. Semiconductor wafer 1453 includes a silicon substrate or other proper substrate having material layers formed thereon. Semiconductor wafer 1453 further includes one or more of various doped regions, dielectric features, multilevel interconnects, and the like (formed at subsequent manufacturing steps).

In some embodiments, an IC includes a voltage source configured to generate a first voltage having a temperature-dependent voltage level, and a VCO including a feedback path and a first VCO cell configured to receive the first voltage, wherein the first VCO cell includes a series of stages, a first stage of the series of stages is configured to output a first signal internal to the first VCO cell based on the voltage level of the first voltage and an oscillation signal propagated on the feedback path, and a last stage of the series of stages is configured to output a second signal external to the first VCO cell based on the first signal and the voltage level of the first voltage. In some embodiments, the first VCO cell includes first and second dummy gate structures, each stage of the series of stages includes an inverter configured to receive the first voltage, the corresponding inverters are arranged in an array between the first and second dummy gate structures, and the array includes a total number of rows equal to one, two, or four. In some embodiments, the first VCO cell includes third and fourth dummy gate structures positioned between the first and second dummy gate structures, a first subset of the array of inverters is positioned between the first and third dummy gate structures, a second subset of the array of inverters is positioned between the second and fourth dummy gate structures, and the voltage source is positioned between the third and fourth dummy gate structures. In some embodiments, the IC includes a fifth dummy gate structure positioned between the voltage source and the third dummy gate structure and offset from the third dummy gate structure by a first multiple of a gate pitch, and a sixth dummy gate structure positioned between the voltage source and the fourth dummy gate structure and offset from the fourth dummy gate structure by a second multiple of the gate pitch. In some embodiments, each stage of the series of stages includes first and second PMOS transistors and first and second NMOS transistors coupled in series between a power supply node configured to have a power supply voltage and a reference voltage node configured to have a reference voltage, the first PMOS transistor is coupled to the power supply node and includes a gate configured to receive the reference voltage, the first NMOS transistor is coupled to the reference voltage node and includes a gate configured to receive the first voltage, the second PMOS and NMOS transistors of the first stage are coupled between the first PMOS and NMOS transistors and include gates configured to receive the oscillation signal, and the second PMOS and NMOS transistors of the last stage are coupled between the first PMOS and NMOS transistors and include gates configured to receive the first signal or a third signal internal to the VCO cell. In some embodiments, the series of stages includes first and second internal stages, the second PMOS and NMOS transistors of the first internal stage include gates configured to receive the first signal and are configured to output a fourth signal internal to the first VCO cell based on the first signal and the voltage level of the first voltage, and the second PMOS and NMOS transistors of the second internal stage include gates configured to receive the fourth signal and are configured to output the third signal based on the fourth signal and the voltage level of the first voltage. In some embodiments, each of the first and second internal stages includes a third PMOS transistor coupled between the first and second PMOS transistors and a third NMOS transistor coupled between the first and second NMOS transistors, wherein the third PMOS and NMOS transistors include gates coupled to the gates of the second PMOS and NMOS transistors, and source terminals of the second PMOS and NMOS transistors are coupled to each other and to drain terminals of the third PMOS and NMOS transistors. In some embodiments, the series of stages includes a plurality of additional internal stages coupled between the first and second internal stages. In some embodiments, each stage of the series of stages includes first PMOS and NMOS transistors coupled in series between a power supply node configured to have a power supply voltage and a reference voltage node configured to have a reference voltage, wherein the first PMOS transistor includes a gate configured to receive the reference voltage and the first NMOS transistor includes a gate configured to receive the first voltage, first and second branches of PMOS transistors coupled between the power supply node and the first PMOS transistor, and first and second branches of NMOS transistors coupled between the first NMOS transistor and the reference voltage node, wherein the first branches of PMOS and NMOS transistors are configured to receive first input signals responsive to a first logic level of a select signal, and the second branches of PMOS and NMOS transistors are configured to receive second input signals responsive to a second logic level of the select signal. In some embodiments, the first VCO cell includes the voltage source. In some embodiments, the VCO includes a second VCO cell coupled between the first VCO cell and the feedback path. In some embodiments, the IC includes a frequency measurement circuit coupled to the VCO and configured to generate an output signal based on a frequency of the oscillation signal.

In some embodiments, a method of manufacturing an IC includes constructing a plurality of gate structures on a plurality of transistor features positioned in a semiconductor substrate, thereby forming multiple stages of a VCO cell between first and second dummy gate structures of the plurality of gate structures, and forming electrical connections including a feedback path and connections from each stage of the multiple stages to a temperature-dependent voltage source, thereby forming a VCO comprising the VCO cell, wherein forming the multiple stages of the VCO cell includes forming an array of inverters between the first and second dummy gate structures, and the array includes a total number of rows equal to one, two, or four. In some embodiments, forming the multiple stages of the VCO cell includes forming third and fourth dummy gate structures between the first and second dummy gate structures, forming a first subset of the array of inverters between the first and third dummy gate structures, and forming a second subset of the array of inverters between the second and fourth dummy gate structures, and constructing the plurality of gate structures includes forming the voltage source between the third and fourth dummy gate structures. In some embodiments, forming the multiple stages of the VCO cell includes constructing a fifth dummy gate structure between the voltage source and the third dummy gate structure, and constructing a sixth dummy gate structure between the voltage source and the fourth dummy gate structure. In some embodiments, the method includes forming electrical connections from the VCO to a frequency measurement circuit.

In some embodiments, a method of generating an IC layout diagram includes arranging a multistage VCO cell in the IC layout diagram, wherein the multistage VCO cell includes an array of inverters positioned between first and second dummy gate regions, and the array includes a total number of rows equal to one, two, or four, configuring electrical connections from a temperature-dependent voltage source to each stage of the VCO cell, and storing the IC layout diagram in a storage device. In some embodiments, the VCO cell includes third and fourth dummy gate regions positioned between the first and second dummy gate regions, a first subset of the array of inverters is positioned between the first and third dummy gate regions, a second subset of the array of inverters is positioned between the second and fourth dummy gate regions, and configuring the electrical connections from the temperature-dependent voltage source to each stage of the VCO cell includes configuring electrical connections from the voltage source positioned between the third and fourth dummy gate regions. In some embodiments, the VCO cell includes a fifth dummy gate region positioned between the voltage source and the third dummy gate region and a sixth dummy gate region positioned between the voltage source and the fourth dummy gate region. In some embodiments, the third and fifth dummy gate regions are offset from each other by a first multiple of a gate pitch, and the fourth and sixth dummy gate regions are offset from each other by a second multiple of the gate pitch.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. An integrated circuit (IC) comprising:
a voltage source configured to generate a first voltage having a temperature-dependent voltage level; and
a voltage-controlled oscillator (VCO) comprising a feedback path and a first VCO cell configured to receive the first voltage,
wherein
the first VCO cell comprises a series of stages,
a first stage of the series of stages is configured to output a first signal internal to the first VCO cell based on the voltage level of the first voltage and an oscillation signal propagated on the feedback path, and
a last stage of the series of stages is configured to output a second signal external to the first VCO cell based on the first signal and the voltage level of the first voltage.

2. The IC of claim 1, wherein
the first VCO cell comprises first and second dummy gate structures,
each stage of the series of stages comprises an inverter configured to receive the first voltage,
the corresponding inverters are arranged in an array between the first and second dummy gate structures, and
the array comprises a total number of rows equal to one, two, or four.

3. The IC of claim 2, wherein
the first VCO cell further comprises third and fourth dummy gate structures positioned between the first and second dummy gate structures,
a first subset of the array of inverters is positioned between the first and third dummy gate structures,
a second subset of the array of inverters is positioned between the second and fourth dummy gate structures, and
the voltage source is positioned between the third and fourth dummy gate structures.

4. The IC of claim 3, further comprising:
a fifth dummy gate structure positioned between the voltage source and the third dummy gate structure and offset from the third dummy gate structure by a first multiple of a gate pitch; and
a sixth dummy gate structure positioned between the voltage source and the fourth dummy gate structure and offset from the fourth dummy gate structure by a second multiple of the gate pitch.

5. The IC of claim 1, wherein
each stage of the series of stages comprises first and second PMOS transistors and first and second NMOS transistors coupled in series between a power supply node configured to have a power supply voltage and a reference voltage node configured to have a reference voltage,
the first PMOS transistor is coupled to the power supply node and comprises a gate configured to receive the reference voltage,
the first NMOS transistor is coupled to the reference voltage node and comprises a gate configured to receive the first voltage,
the second PMOS and NMOS transistors of the first stage are coupled between the first PMOS and NMOS transistors and comprise gates configured to receive the oscillation signal, and
the second PMOS and NMOS transistors of the last stage are coupled between the first PMOS and NMOS transistors and comprise gates configured to receive the first signal or a third signal internal to the VCO cell.

6. The IC of claim 5, wherein
the series of stages comprises first and second internal stages,
the second PMOS and NMOS transistors of the first internal stage comprise gates configured to receive the first signal and are configured to output a fourth signal internal to the first VCO cell based on the first signal and the voltage level of the first voltage, and
the second PMOS and NMOS transistors of the second internal stage comprise gates configured to receive the fourth signal and are configured to output the third signal based on the fourth signal and the voltage level of the first voltage.

7. The IC of claim 6, wherein each of the first and second internal stages further comprises:
a third PMOS transistor coupled between the first and second PMOS transistors and a third NMOS transistor coupled between the first and second NMOS transistors,
wherein
the third PMOS and NMOS transistors comprise gates coupled to the gates of the second PMOS and NMOS transistors, and
source terminals of the second PMOS and NMOS transistors are coupled to each other and to drain terminals of the third PMOS and NMOS transistors.

8. The IC of claim 6, wherein
the series of stages comprises a plurality of additional internal stages coupled between the first and second internal stages.

9. The IC of claim 1, wherein each stage of the series of stages comprises:
first PMOS and NMOS transistors coupled in series between a power supply node configured to have a power supply voltage and a reference voltage node configured to have a reference voltage, wherein the first PMOS transistor comprises a gate configured to receive the reference voltage and the first NMOS transistor comprises a gate configured to receive the first voltage;
first and second branches of PMOS transistors coupled between the power supply node and the first PMOS transistor; and
first and second branches of NMOS transistors coupled between the first NMOS transistor and the reference voltage node,
wherein
the first branches of PMOS and NMOS transistors are configured to receive first input signals responsive to a first logic level of a select signal, and
the second branches of PMOS and NMOS transistors are configured to receive second input signals responsive to a second logic level of the select signal.

10. The IC of claim 1, wherein the first VCO cell comprises the voltage source.

11. The IC of claim 1, wherein the VCO further comprises:
a second VCO cell coupled between the first VCO cell and the feedback path.

12. The IC of claim 1, further comprising:
a frequency measurement circuit coupled to the VCO and configured to generate an output signal based on a frequency of the oscillation signal.

13. A method of manufacturing an integrated circuit (IC), the method comprising:
constructing a plurality of gate structures on a plurality of transistor features positioned in a semiconductor substrate, thereby forming multiple stages of a voltage-controlled oscillator (VCO) cell between first and second dummy gate structures of the plurality of gate structures; and
forming electrical connections including a feedback path and connections from each stage of the multiple stages to a temperature-dependent voltage source, thereby forming a VCO comprising the VCO cell,
wherein
the forming the multiple stages of the VCO cell comprises forming an array of inverters between the first and second dummy gate structures, and
the array comprises a total number of rows equal to one, two, or four.

14. The method of claim 13, wherein
the forming the multiple stages of the VCO cell further comprises:
forming third and fourth dummy gate structures between the first and second dummy gate structures;
forming a first subset of the array of inverters between the first and third dummy gate structures; and
forming a second subset of the array of inverters between the second and fourth dummy gate structures, and
the constructing the plurality of gate structures comprises forming the voltage source between the third and fourth dummy gate structures.

15. The method of claim 14, wherein the forming the multiple stages of the VCO cell further comprises:
constructing a fifth dummy gate structure between the voltage source and the third dummy gate structure; and
constructing a sixth dummy gate structure between the voltage source and the fourth dummy gate structure.

16. The method of claim 13, further comprising:
forming electrical connections from the VCO to a frequency measurement circuit.

17. A method of generating an integrated circuit (IC) layout diagram, the method comprising:
arranging a multistage VCO cell in the IC layout diagram, wherein
the multistage VCO cell comprises an array of inverters positioned between first and second dummy gate regions, and
the array comprises a total number of rows equal to one, two, or four;
configuring electrical connections from a temperature-dependent voltage source to each stage of the VCO cell; and
storing the IC layout diagram in a storage device.

18. The method of claim 17, wherein
the VCO cell further comprises third and fourth dummy gate regions positioned between the first and second dummy gate regions,
a first subset of the array of inverters is positioned between the first and third dummy gate regions,
a second subset of the array of inverters is positioned between the second and fourth dummy gate regions, and
the configuring the electrical connections from the temperature-dependent voltage source to each stage of the VCO cell comprises configuring electrical connections from the voltage source positioned between the third and fourth dummy gate regions.

19. The method of claim 18, wherein the VCO cell further comprises:
a fifth dummy gate region positioned between the voltage source and the third dummy gate region; and
a sixth dummy gate region positioned between the voltage source and the fourth dummy gate region.

20. The method of claim 19, wherein
the third and fifth dummy gate regions are offset from each other by a first multiple of a gate pitch, and
the fourth and sixth dummy gate regions are offset from each other by a second multiple of the gate pitch.
